(19) United States
(12) Patent Application Publication
(10) Pub. No.: US 2007/0045230 A1
(43) Pub. Date: Mar. 1, 2007

(54) Methods for independently controlling one or more etching parameters in the manufacture of microfeature devices

(75) Inventors: David J. Keller, Boise, ID (US); Larson Lindholm, Boise, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/215,213

(22) Filed: Aug. 30, 2005

(51) Int. Cl. B44C 1/22; H01L 21/306; C23F 1/00

(52) U.S. Cl. 216/81; 216/74; 156/345.24

(57) ABSTRACT

Methods for independently controlling one or more etching parameters in the manufacture of microfeature devices are disclosed herein. One particular embodiment of such a method comprises fabricating a microfeature device on a microfeature workpiece. The workpiece includes a first portion with features having first critical dimensions and a second portion with features having second critical dimensions different than the first critical dimensions. The workpiece also includes a carbon-based layer over at least a portion of the first portion and the second portion. The method includes setting an etching parameter to control the etching process in the first portion of the workpiece relative to and independently of the etching process in the second portion of the workpiece, and etching the carbon-based layer.

### TECHNICAL FIELD

The present invention is directed generally toward methods for independently controlling one or more etching parameters in the manufacture of microfeature devices.

### BACKGROUND

Microfeature devices generally have a die (i.e., a chip) that includes a high density of very small components, such as integrated circuitry and an array of very small bond-pads electrically coupled to the integrated circuitry. The bond-pads are the external electrical contacts on the die through which supply voltage, signals, etc., are transmitted to and from the integrated circuitry. In a typical fabrication process, a large number of dies are manufactured on a single workpiece using many different processes that may be repeated at various stages (e.g., implanting, doping, photolithography, deposition, etching, plating, planarizing, etc.) to form trenches, vias, holes, implant regions, and other features on the workpiece that ultimately become semiconductor components, conductive lines, and other microelectronic features (e.g., gates and other structures). Lithographic processes, for example, generally include depositing a layer of radiation-sensitive photoresist material on the workpiece, positioning a patterned mask or reticle over the photoresist layer, and exposing the masked photoresist layer to a selected radiation. After the exposing step, a developing step involves removing one of either the exposed or unexposed portions of photoresist. Complex patterns typically require multiple exposure and development steps.

The workpiece is then subjected to an etching process. In an anisotropic etching process, for example, the etchant removes exposed material, but not material protected beneath the remaining portions of the photoresist layer. Accordingly, the etchant creates a pattern of openings (e.g., trenches, vias, or holes) in the workpiece material or in materials deposited on the workpiece. These openings can be filled with dielectric, conductive, and/or semiconductive materials to build layers of microelectronic features on the workpiece. The dies are then separated from one another (i.e., singulated) by dicing the workpiece and backgrinding the individual dies. After the dies have been singulated, they are typically “packaged” to couple bond-pads on the dies to a larger array of electrical terminals that can be more easily coupled to the various power supply lines, signal lines, and ground lines.

As microfeature devices become more complex, there is a drive to continually decrease the size of the individual features and increase the density of the features across the workpiece. This significantly increases the complexity of processing workpieces because it is increasingly difficult to form such small features on the workpiece. In some processes, the dimensions (referred to as critical dimensions) of selected features are evaluated as a diagnostic measure to determine whether the dimensions of other features comply with manufacturing specifications. Critical dimensions are accordingly most likely to suffer from errors resulting from any of a number of aspects of the foregoing fabrication processes. Such errors can include errors generated by the radiation source and/or the optics used in lithographic processes. The critical dimensions can also be affected by errors in processes occurring before or during the exposure/development process (such as problems with the photoresist material), errors occurring during etching processes, and/or variations in material removal processes (e.g., chemical-mechanical planarization processes).

One area of particular concern in lithographic processing is accurately focusing the pattern onto the surface of the workpiece and maintaining the integrity of the pattern throughout the subsequent processes with little or no critical dimension bias. Critical dimension bias is the difference in a feature's measurement before and after a process flow step, such as comparing the dimension of a feature before etching and after an etch is completed. One problem with conventional lithographic processes is that many photoresist materials do not maintain crisp edges throughout etching and tend to bend, wrinkle, and/or shred. These defects are undesirable because they may be transferred to the underlying layers and often result in significant critical dimension bias. This problem is further exacerbated as the size of microfeature devices (and in turn, the critical dimensions of these features) continues to shrink.

One conventional approach addressing the photoresist material problem is to deposit a carbon-based layer under the photoresist material and use the photoresist material to form a patterned carbon-based layer. The photoresist material is then removed and the carbon-based layer can act as a mask or sacrificial layer when etching the remaining underlying material layers. FIG. 1, for example, is a side cross-sectional view of a workpiece 10 at an intermediate stage in a process of forming a microelectronic feature (e.g., a gate or other structure) on the workpiece 10. The workpiece 10 includes a carbon-based layer 20 that has been patterned in previous processing steps. The carbon-based layer 20 is on a stack of underlying layers, including a dielectric layer 22 (e.g., a nitride layer), a conductive layer 24 (e.g., a tungsten layer), and a polysilicon layer 26. The patterned carbon-based layer 20 includes a first portion 30 (e.g., an array portion) having a plurality of columns 32 (three columns are shown in FIG. 1 as columns 32a-c) and a second portion 40 (e.g., a periphery portion) having a plurality of columns 42 (two columns are shown in FIG. 1 as columns 42a and 42b). The features in the array portion 30 have a critical dimension of D₁ and the features in the periphery portion 40 have a critical dimension of D₂.

One concern with this arrangement is that the pattern of features in the array portion 30 and the periphery portion 40 cannot be changed relative to and independently of each other with conventional etching processes. For example, if the critical dimensions in one portion of the workpiece 10 need to be adjusted or tuned (e.g., because the device has leakage or does not operate fast enough), conventional processes require either (a) multiple lithographic processes to form a pattern in the array portion independently of a pattern in the periphery portion before etching, or (b) a “best fit” adjustment to the critical dimensions across the entire workpiece during etching. One problem with the additional lithographic processes is that such processing is very expensive and time-consuming (e.g., requires additional masks, reticles, and/or requalification of the lithographic tools). The “best fit” approach also includes several drawbacks. Referring to FIG. 1, for example, if the feature size of columns 42a and 42b is decreased (as shown in broken lines) to change the critical dimension from D₂ to D₄, the feature size in the array portion 30 is also affected, thus decreasing the critical dimension in the array portion from D₁ to D₃. In many cases, this can negatively affect the performance and/or operability of the resulting microfeature device. Accordingly, there is a need to improve the etching processes used in the manufacture of microfeature devices.

### BRIEF DESCRIPTION OF THE DRAWINGS

FIG. 1 is a side cross-sectional view of an intermediate stage in a method of forming a gate or other structure on a microfeature workpiece in accordance with the prior art.

FIGS. 2A-2C are stages in a method of forming a gate or other structure in a microfeature workpiece in accordance with an embodiment of the invention.

FIG. 3 is a chart illustrating the independent control of critical dimensions in a first portion of a workpiece relative to and independent of a second portion of the workpiece based on varying one or more etching parameters.

FIG. 4A illustrates a stage in a method of forming a gate or other structure in a microfeature workpiece in accordance with another embodiment of the invention.

FIG. 4B illustrates a stage in a method of forming a gate or other structure in a microfeature workpiece in accordance with still another embodiment of the invention.

FIG. 5 is a block diagram illustrating an etching system in accordance with an embodiment of the invention.

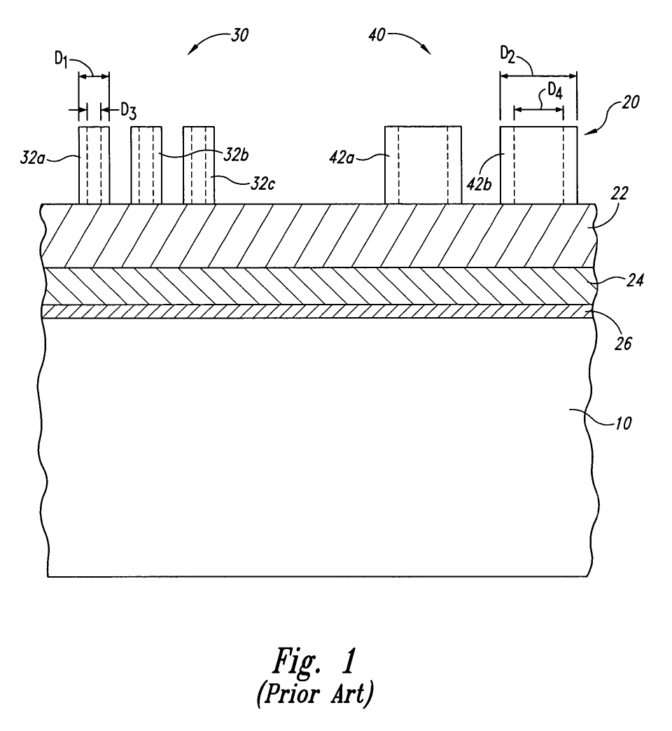

### DETAILED DESCRIPTION

A. Overview/Summary

The following disclosure describes several embodiments of methods for independently controlling one or more etching parameters in the manufacture of microfeature devices. One aspect of the invention is directed toward a method for fabricating a microfeature device on a microfeature workpiece. The workpiece includes a first portion with features having first critical dimensions and a second portion with features having second critical dimensions different than the first critical dimensions. The workpiece also includes a carbon-based layer over at least a portion of the first portion and the second portion. The method includes setting an etching parameter to control the etching process in the first portion of the workpiece relative to and independently of the etching process in the second portion of the workpiece, and etching the carbon-based layer. The etching parameter can be set before the etching process and held constant while etching the carbon-based layer, or the etching parameter can be set by changing the parameter while etching the carbon-based layer for dynamic etching.

Several different etching parameters (e.g., flow of Cl₂, bias power) can be selected to control the etching process in the first portion relative to the second portion. For example, increasing the flow of Cl₂ can increase the second critical dimensions in the second portion of the workpiece while holding the first critical dimensions in the first portion of the workpiece generally constant. Likewise, decreasing the flow of Cl₂ during etching can decrease the second critical dimensions in the second portion of the workpiece while holding the first critical dimensions in the first portion generally constant. Increasing the bias power during etching decreases the first critical dimensions in the first portion of the workpiece while keeping the second critical dimensions in the second portion generally constant, while decreasing the bias power increases the first critical dimensions in the first portion of the workpiece while keeping the second critical dimensions in the second portion generally constant.

Another embodiment of a method for etching material during the fabrication of a microfeature device includes providing a microfeature workpiece having an array portion, a periphery portion, and a carbon-based layer. The carbon-based layer on the workpiece is over at least a portion of the array portion and the periphery portion of the workpiece. The method further includes etching the carbon-based layer using an etchant including O₂/Cl₂/SiCl₄, and selectively setting and/or varying one or more etching parameters to control the etching process in the array portion relative to and independently of the etching process in the periphery portion.

Still another embodiment of the invention is directed to a method for etching material on a workpiece in the formation of a gate structure. The workpiece can include an array portion, a periphery portion at least partially surrounding the array portion, and a carbon-based layer. The carbon-based layer is over at least a portion of the array portion and the periphery portion. The method includes etching the carbon-based layer using an etchant including O₂/Cl₂/SiCl₄. The method further includes tuning the etching process in the array portion relative to and independently of the etching process in the periphery portion by selectively varying one or more etching parameters while etching the carbon-based layer.

Additional embodiments of the invention are directed toward an apparatus for etching a microfeature workpiece. The apparatus includes an etching chamber and a workpiece positioned in the chamber for etching. The workpiece can include a first portion with features having first critical dimensions, a second portion with features having second critical dimensions different than the first critical dimensions, and a carbon-based layer. The carbon-based layer is over at least part of the first and second portions of the workpiece. The apparatus also includes a controller operably coupled to the etching chamber. The controller can include a computer-readable medium containing instructions to perform a method comprising (a) etching the carbon-based layer, and (b) setting an etching parameter to control the etching process in the first portion of the workpiece relative to and independently of the etching process in the second portion of the workpiece. The etching parameter can be set before the etching process and held constant while etching the carbon-based layer, or the etching parameter can be set by changing the parameter while etching the carbon-based layer for dynamic etching.

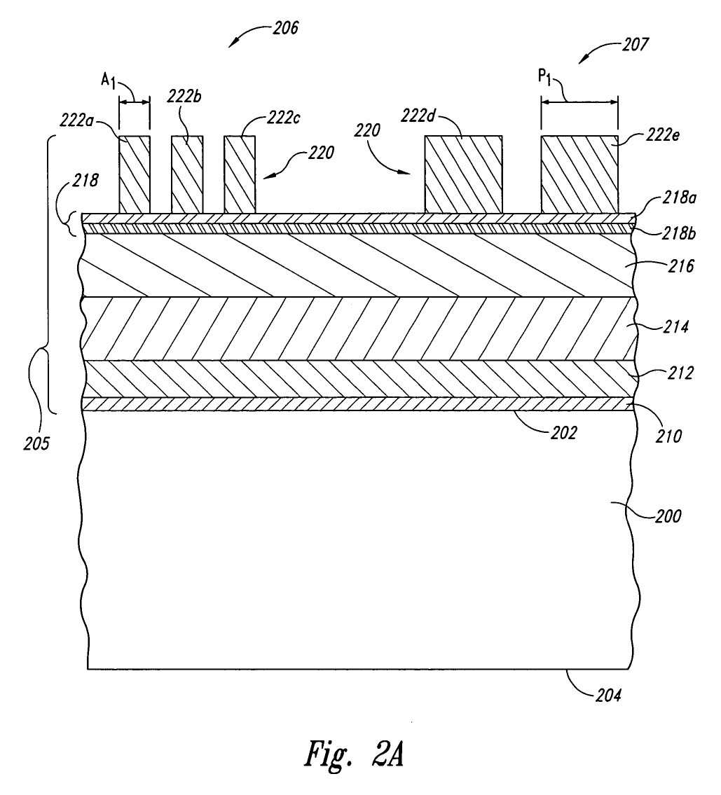

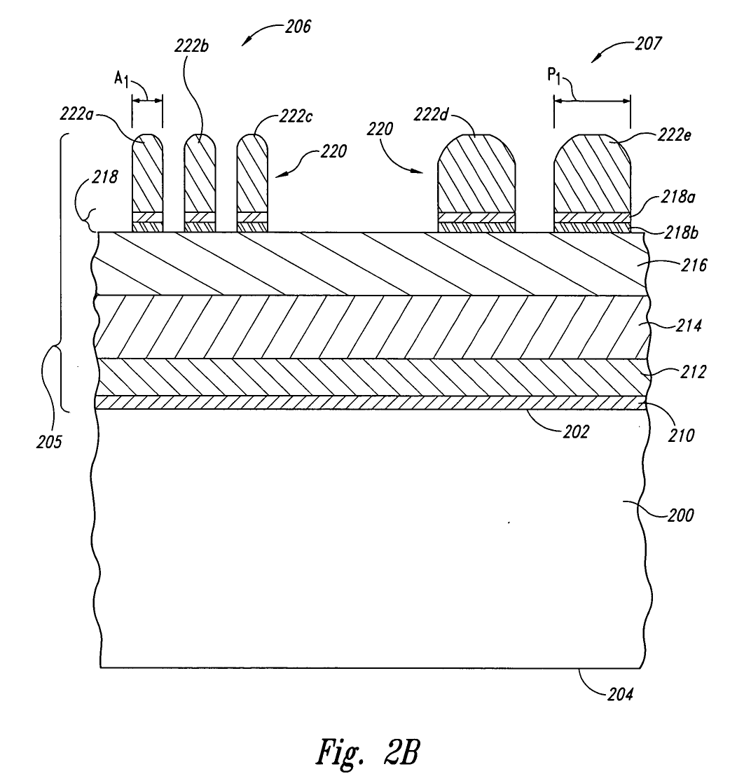

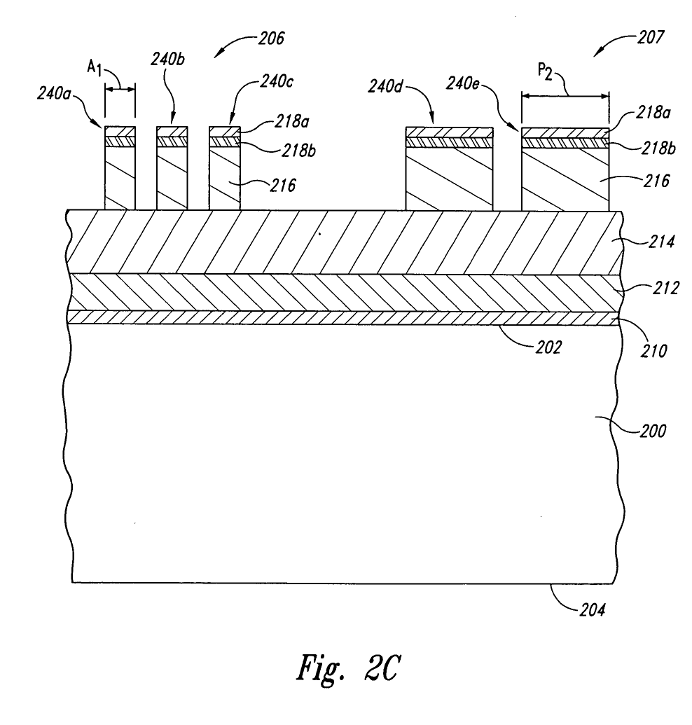

The term “microfeature workpiece” is used throughout to include substrates upon which and/or in which microelectronic circuits or components, data storage elements or layers, vias or conductive lines, micro-optic features, micromechanical features, optics, and/or microbiological features are or can be fabricated. For example, microfeature workpieces can be semiconductor wafers, glass substrates, dielectric substrates, or many other types of substrates. Microfeature workpieces generally have at least several features with critical dimensions less than or equal to 1 μm, and in many applications the critical dimensions of the smaller features on microfeature workpieces are less than 0.25 μm or even less than 0.1 μm. Many specific details of certain embodiments of the invention are set forth in the following description and in FIGS. 2A-5 to provide a thorough understanding of these embodiments. A person skilled in the art, however, will understand that the invention may be practiced without several of these details, or additional details can be added to the invention. Well-known structures and functions have not been shown or described in detail to avoid unnecessarily obscuring the description of the embodiments of the invention. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature and/or additional types of features are not precluded.

B. Methods for Independently Controlling One or More Etching Parameters in the Manufacture of Microfeature Devices

FIGS. 2A-2C illustrate various stages in a method of etching a microfeature workpiece in accordance with an embodiment of the invention. More specifically, FIGS. 2A-2C illustrate stages of a method for independently controlling one or more etching parameters for etching a carbon-based layer on the workpiece during the formation of gates or other structures in and/or on the workpiece.

FIG. 2A is a side cross-sectional view of a portion of a microfeature workpiece 200 at an initial stage before the gate structures have been formed. The workpiece 200 includes a first side 202 and a second side 204 opposite the first side 202. In previous processing steps, a stack of layers 205 was deposited onto the first side 202 of the workpiece 200. The stack of layers 205 can include a gate oxide layer (not shown) at the first side 202 of the workpiece 200 and a polysilicon layer 210 applied over the gate oxide layer. The gate oxide layer is an optional layer that may be omitted in several embodiments. The stack of layers 205 can further include a conductive layer 212 deposited onto the polysilicon layer 210. The conductive layer 212 may include tungsten, copper, aluminum, tin, titanium, or any other suitable metal or conductive material. A dielectric layer 214 was deposited over the conductive layer 212. The dielectric layer 214 can include a nitride layer, an oxide layer, or a layer of any other suitable non-conductive material. A carbon-based layer 216 was deposited over the dielectric layer 214 and an anti-reflective layer 218 was deposited onto the carbon-based layer 216. In the illustrated embodiment, the anti-reflective layer 218 includes a bottom anti-reflective coating (BARC) layer 218a and a dielectric anti-reflective coating (DARC) layer 218b. In other embodiments, however, the anti-reflective layer 218 may have a different number of layers and/or include different materials. A resist layer 220 was deposited onto the BARC layer 218a and patterned to form a plurality of first columns 222 or gate structures (five are shown in FIG. 2A as columns 222a-222e). In subsequent processing steps, the various layers of the stack 205 can be etched to transfer the pattern from the resist layer 220 into the underlying material layers.

The first columns 222a-c are at a first portion 206 (e.g., an array portion) over the workpiece 200 and the first columns 222d and 222e are at a second portion 207 (e.g., a periphery portion) over the workpiece 200. Microfeature devices (e.g., memory devices) such as those being formed using the workpiece 100 can include both an array of memory cells and peripheral circuits. The array of memory cells store information, and may be referred to as an array or a storage aspect of a memory device. The array may require a high density of components so that a large amount of information can be stored within a limited amount of space. The peripheral circuits often need to quickly process signals, such as timing, address, and data, so as to access the array to read or to write information. Such peripheral circuits may be referred to as a periphery or a logic aspect of a memory device. The periphery may require high speed to operate with the demand of a fast central processing unit. Accordingly, both high speed and high density are required for memory devices. In the illustrated embodiment, for example, the array portion 206 can include a number of devices or first features, such as memory cells, that coexist in close proximity with each other. The periphery portion 207 can include a number of devices or second features that operate at high speed, such as timing circuits and decoders. For purposes of illustration, only three devices (represented by first columns 222a-c) are shown in the array portion 206 and only two devices (represented by first columns 222d and 222e) are illustrated in the periphery portion 207. Although only five first columns 222 are shown in FIG. 2A, it will be appreciated that the workpiece 200 may include any number of first columns 222 formed in a desired arrangement on the workpiece 200. Furthermore, in other embodiments the stack of layers 205 may include additional layers and/or one or more of the layers described above may be omitted.

The individual first columns 222a-c in the array portion 206 have a critical dimension of A₁ and the first columns 222d and 222e in the periphery portion 207 have a critical dimension of P₁. As discussed below in more detail, several embodiments of the present invention allow the critical dimension A₁ and/or the critical dimension P₁ to be adjusted or “tuned” relative to and independently of each other by selectively changing one or more etching parameters before and/or while etching the carbon-based layer 216.

Referring next to FIG. 2B, the BARC and DARC layers 218a and 218b are etched using a suitable etching process. In several embodiments, for example, the BARC and DARC layers 218a and 218b can be etched using an etchant that removes all or substantially all the exposed portions of the BARC and DARC layers 218a and 218b without negatively affecting the underlying carbon-based layer 216 or the remaining resist layer 220.

Referring next to FIG. 2C, the carbon-based layer 216 is etched using a suitable etching process, such as a dry develop process, to form second columns 240 (three are shown in the array portion 206 as second columns 240a-c and two are shown in the periphery portion 207 as second columns 240d and 240e). The carbon-based layer 216 can be etched in a high-density etch chamber that includes independent control of ion density and ion energy. The etching parameters (e.g., chamber pressure, upper (TCP) power, substrate bias, and chemical flow rates) can vary depending on the desired configuration of the gate or structure to be fabricated. In several embodiments, for example, the carbon-based layer 216 can be etched in a chamber having a pressure in a range of approximately 5-20 milliTorr, a TCP power in the range of approximately 200-1000 watts, and a bias power in the range of approximately 150-500 volts. In other embodiments, the parameters may have different ranges depending upon the materials used, the thickness of the materials, and the desired configuration of the device structures to be formed.

The carbon-based layer 216 can be etched using an etchant including O₂/Cl₂/SiCl₄. The flow rate of O₂ can be approximately 40-200 standard cubic centimeters per minute (sccm), the flow rate of Cl₂ can be approximately 10-100 sccm, and the flow rate of SiCl₄ can be approximately 0.5-5 sccm. The proper ratio of materials in the etchant can provide a generally anisotropic etch (i.e., the sidewalls of the etched carbon-based layer 216 will be generally normal to the first side 202 of the workpiece 200). In one embodiment, for example, the etchant may include a ratio of O₂ to Cl₂ to SiCl₄ of approximately 1/2/0.03. In other embodiments, the ratio may be different.

In additional processing steps not described in detail herein, the dielectric layer 214 can be etched using the carbon-based layer 216 as a mask. The carbon-based layer 216 can then be removed from the workpiece 200 and the workpiece can undergo further processing to complete the construction of gates or other structures in the workpiece 200.

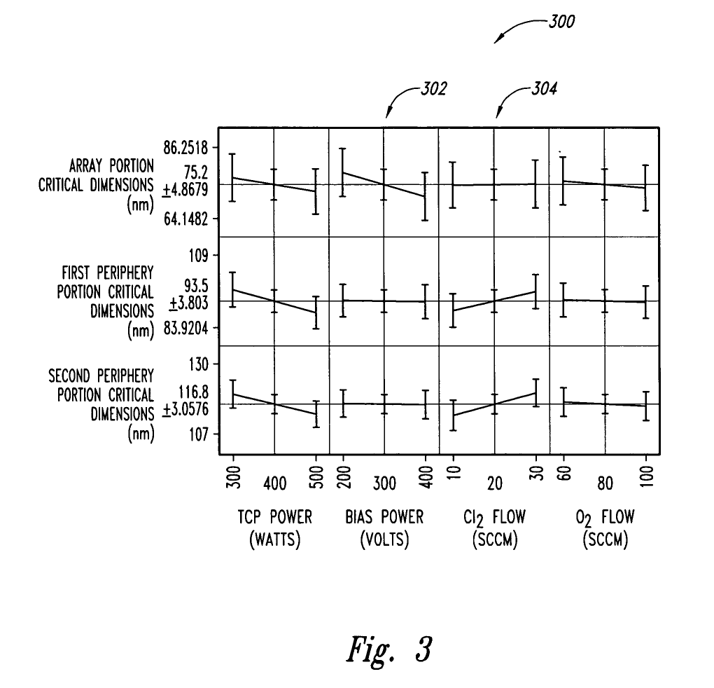

One aspect of the method described above for etching the carbon-based layer 216 is that the critical dimensions in a first area can been controlled relative to and independently of the critical dimensions in a second area by selectively varying or otherwise selecting one or more of the etching parameters to achieve a desired result. FIG. 3, for example, is a chart 300 illustrating the independent control of critical dimensions in an array portion (e.g., the array portion 206 of the workpiece 200) relative to critical dimensions in first and second periphery portions (e.g., the periphery portion 207 of the workpiece 200) based on adjusting various etching parameters (e.g., TCP power, bias power, flow rate of Cl₂, and flow rate of O₂). Referring to column 302 of the chart 300, for example, increasing the bias power decreases the critical dimensions in the array portion while holding the critical dimensions in the first and second periphery portions generally constant. As shown in column 304, however, increasing the flow of Cl₂ increases the critical dimensions in the first and second periphery portions while keeping the critical dimensions in the array portion generally constant.

FIGS. 2C and 3 together illustrate one example of controlling the critical dimensions in the periphery portion 207 relative to and independently of the critical dimensions in the array portion 206 by using a higher flow rate of Cl₂ relative to a previous flow rate of Cl₂ for etching the carbon-based layer 216. More specifically, the size of the post-etch columns 240a-c in the array portion 206 can be generally similar to pre-etch columns 222a-c (FIG. 2B) and, accordingly, the critical dimensions of these features remains approximately A₁. The post-etch columns 240d and 240e in the periphery portion 207 of the workpiece 200, however, are smaller than pre-etch columns 222d and 222e (FIG. 2B) and, accordingly, the critical dimensions of the columns 240d and 240e in the periphery portion 207 has increased to P₂.

The following table illustrates selectively setting and/or changing an etching parameter relative to a prior setting for the etching parameter to control the etching process of a carbon-based layer in a first portion of a workpiece having features with first critical dimensions relative to and independently of a second portion of the workpiece having features with second critical dimensions. The feature sizes in the first portion can be less than 90 nm and the feature sizes in the second portion can be less than 110 nm, although the features in the first and second portions may have different sizes in different embodiments. The carbon-based layer can be etched with an etchant including O₂/Cl₂/SiCl₄ and the above-described ranges of etching parameters (e.g., chamber pressure, TCP power, substrate bias, and chemical flow rates).

| | CHANGE IN ETCHING PARAMETER | | |
|---|---|---|---|
| | RELATIVE TO PRIOR SETTING | | |
| | TO ACHIEVE OBJECTIVE | | |
| | BIAS | FLOW | FLOW |
| OBJECTIVE | POWER | OF Cl₂ | OF SiCl₄ |
| Achieve Smaller First | Higher | N/A | N/A |
| Critical Dimensions | | | |
| Without Generally | | | |
| Affecting Second | | | |
| Critical Dimensions | | | |
| Achieve Larger First | Lower | N/A | N/A |
| Critical Dimensions | | | |
| Without Generally | | | |
| Affecting Second | | | |
| Critical Dimensions | | | |
| Achieve Smaller Second | N/A | Lower | N/A |
| Critical Dimensions | | | |
| Without Generally | | | |
| Affecting First | | | |
| Critical Dimensions | | | |
| Achieve Larger Second | N/A | Higher | N/A |
| Critical Dimensions | | | |
| Without Generally | | | |
| Affecting First | | | |
| Critical Dimensions | | | |
| Achieve Larger First | N/A | N/A | Higher |
| and Second Critical | | | |
| Dimensions Without | | | |
| Affecting Generally | | | |
| Affecting Ratio of | | | |
| First Critical | | | |
| Dimensions to Second | | | |
| Critical Dimensions | | | |
| Achieve Smaller First | N/A | N/A | Lower |
| and Second Critical | | | |
| Dimensions Without | | | |
| Affecting Generally | | | |
| Affecting Ratio of | | | |
| First Critical | | | |
| Dimensions to Second | | | |
| Critical Dimensions | | | |

One feature of the methods described above is that selecting one or more etching parameters for etching the carbon-based layer 216 can provide independent control of the critical dimensions in a first portion of the workpiece 200 with respect to the critical dimensions in a second portion of the workpiece 200 where the features have different sizes in the first and second portions. An advantage of this feature is that if the critical dimensions in one portion of the workpiece 200 need to be tuned or adjusted (e.g., because the device has leakage or does not operate fast enough), the critical dimensions can be independently adjusted in that portion without negatively affecting the critical dimensions in other portions of the workpiece 200. This feature can make processing of the workpieces more efficient because precisely tuning the critical dimensions during fabrication in accordance with various manufacturing tolerances and specifications can significantly reduce the time and expense of fabrication and increase throughput.

Another feature of the methods described above is that the proper ratio of materials in the etchant provides a generally anisotropic etch. Many conventional etching processes result in non-anisotropically sloped sidewalls, which can be problematic because they alter the critical dimensions of the device features. One advantage of the methods described above is that anisotropic etches allow for greater precision during the etching process and, accordingly, greater device density. This feature is particularly helpful in further reducing the footprint of microfeature devices.

C. Additional Embodiments of Systems and Methods for Independently Controlling One or More Etching Parameters in the Manufacture of Microfeature Devices

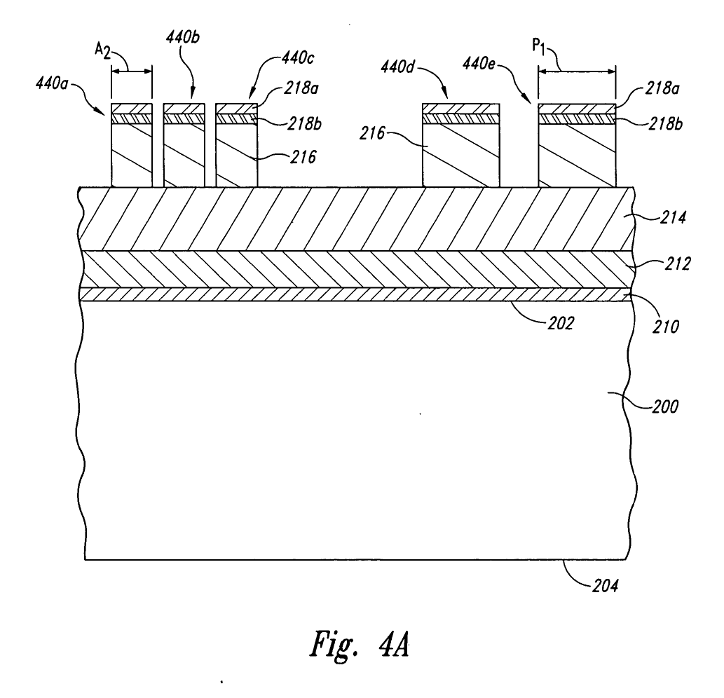

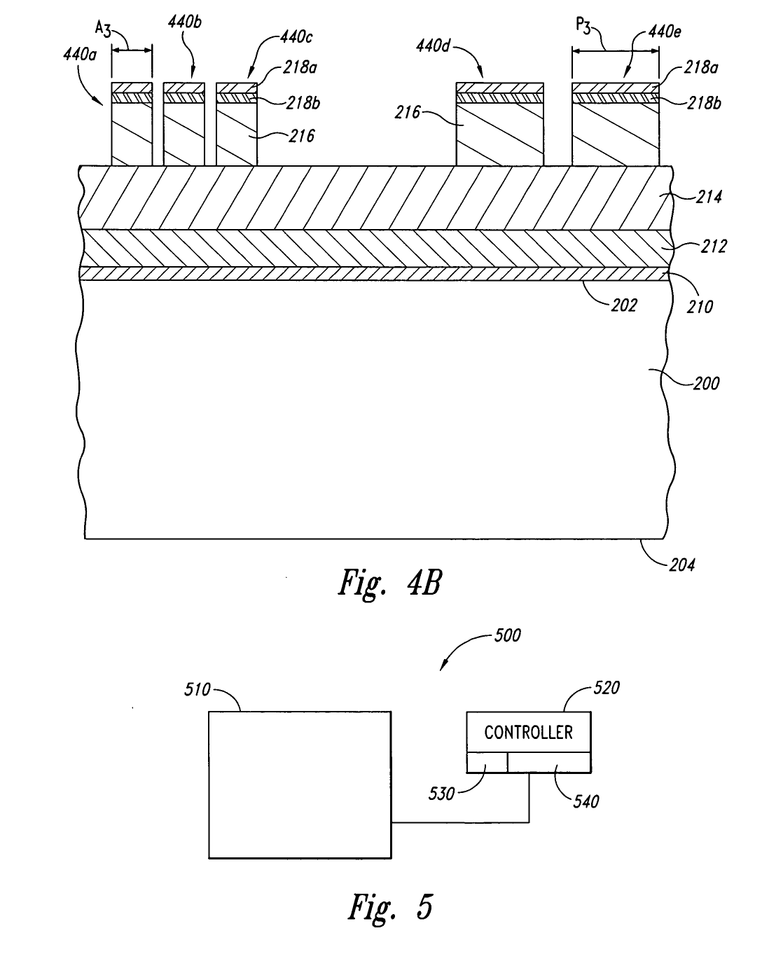

In additional embodiments, the critical dimensions in the array portion 206 can be controlled when etching the carbon-based layer 216 while keeping the critical dimensions in the periphery portion 207 generally constant. Referring to FIG. 4A, for example, the etching process results in a plurality of columns 440 or gate structures (three are shown in the array portion 206 as columns 440a-c and two are shown in the periphery portion 207 as columns 440d and 440e). In one aspect of this embodiment, the critical dimensions in the array portion have been increased from A₁ to A₂, while the critical dimensions P₁ in the periphery portion have remained generally constant. The critical dimensions in the array portion 206 can be controlled (e.g., increased from A₁ to A₂) relative to and independently of the periphery portion 207 by decreasing the bias power, as shown in column 302 of FIG. 3.

In still further embodiments, the critical dimensions in both the array and periphery portions 206 and 207 (i.e., the absolute critical dimensions) of the workpiece 200 can be increased/decreased while holding the array to periphery critical dimension ratio generally constant. Referring to FIG. 4B, for example, by increasing the flow of SiCl₄ relative to the flow of O₂ and Cl₂ during etching, the absolute critical dimensions on the workpiece can be increased from A₁ and P₁ (FIG. 2B) to A₃ and P₃, respectively. Likewise, by decreasing the flow of SiCl₄ relative to the flow of O₂ and Cl₂, the absolute critical dimensions can be decreased (not shown).

FIG. 5 is a schematic diagram of a system 500 configured in accordance with several embodiments of the invention for selectively varying one or more etching parameters while etching the carbon-based layer 216 on the workpiece 200. The system 500 can include an etching chamber 510 and a controller 520 operatively coupled to the etching chamber 510 to control aspects of the etching process. In several embodiments, for example, the controller 520 can include a database 530 including a large number of predetermined process parameters to achieve the desired critical dimensions in the array and/or periphery portions 206 and 207 of the workpiece 200. The controller 520 can further include a computer-operable medium 540 that contains instructions that cause the controller 520 to select a particular set of parameters based on the desired size and position of the critical dimensions on the workpiece 200. The computer-operable medium 540 can be software and/or hardware that evaluates the desired configuration for the critical dimensions on the workpiece 200, examines the database 530 to locate the applicable predetermined process parameters, and configures the etching process in the etching chamber 510 accordingly. In other embodiments, the system 500 may include additional elements and/or have a different configuration.

An example of an etching process using the system 500 can include etching a first workpiece, measuring the features on the first workpiece, and selecting/changing an etching parameter based on the measured feature size of the first workpiece. The method can further include etching a second workpiece with the changed etching parameter. This process can be manual or automatic. Another example of an etching process utilizing the system 500 can include an operator inputting a desired outcome (e.g., feature size) into the computer-operable medium 540 and letting the computer select the appropriate parameter set. The computer can then execute the etching process with the preselected settings.

From the foregoing, it will be appreciated that specific embodiments of the invention have been described herein for purposes of illustration, but that various modifications may be made without deviating from the invention. For example, in alternative embodiments the workpiece 200 may be etched in a different type of etching system, such as a low density system. Additionally, in several embodiments the workpiece 200 may be positioned on a controllable electrostatic chuck during processing to help increase critical dimension uniformity. Furthermore, while the foregoing embodiments are generally related to forming gate structures in microfeature workpieces, the methods described above can also be used in the formation of other microelectronic features or structures. Aspects of the invention described in the context of particular embodiments may be combined or eliminated in other embodiments. For example, several etching parameters may be changed simultaneously to provide more precise control while tuning the critical dimensions. Further, while advantages associated with certain embodiments of the invention have been described in the context of those embodiments, other embodiments may also exhibit such advantages, and not all embodiments need necessarily exhibit such advantages to fall within the scope of the invention. Accordingly, the invention is not limited except as by the appended claims.

1. A method for fabricating a microfeature device on a microfeature workpiece, the workpiece including a first portion with features having first critical dimensions, a second portion with features having second critical dimensions different than the first critical dimensions, and a carbon-based layer over at least a portion of the first portion and the second portion, the method comprising:
etching the carbon-based layer; and
setting an etching parameter to control the etching process in the first portion relative to and independently of the etching process in the second portion.

2. The method of claim 1 wherein etching the carbon-based layer includes etching the carbon-based layer using an etchant comprising O₂/Cl₂/SiCl₄.

3. The method of claim 2 wherein etching the carbon-based layer using an etchant includes using an etchant with a ratio of O₂ to Cl₂ to SiCl₄ of approximately 1/2/0.03.

4. The method of claim 2 wherein etching the carbon-based layer includes etching the carbon-based layer using O₂ having a flow rate of approximately 40-200 sccm, Cl₂ having a flow rate of approximately 10-100 sccm, and SiCl₄ having a flow rate of approximately 0.5-5 sccm.

5. The method of claim 2 wherein setting an etching parameter to control the etching process includes setting a flow rate of Cl₂.

6. The method of claim 5 wherein setting a flow rate of Cl₂ includes setting a higher flow rate of Cl₂ relative to a previous flow rate of Cl₂ to change the second critical dimensions to third critical dimensions greater than the second critical dimensions while holding the first critical dimensions generally constant.

7. The method of claim 5 wherein setting a flow rate of Cl₂ includes setting a lower flow rate of Cl₂ relative to a previous flow rate of Cl₂ to change the second critical dimensions to fourth critical dimensions less than the second critical dimensions while holding the first critical dimensions generally constant.

8. The method of claim 2 wherein setting an etching parameter to control the etching process includes setting a bias power applied to the workpiece during etching.

9. The method of claim 8 wherein setting a bias power applied to the workpiece includes setting a higher bias power relative to a previous bias power to change the first critical dimensions to third critical dimensions less than the first critical dimensions while holding the second critical dimensions generally constant.

10. The method of claim 8 wherein setting a bias power applied to the workpiece includes setting a lower bias power relative to a previous bias power to change the first critical dimensions to third critical dimensions greater than the first critical dimensions while holding the second critical dimensions generally constant.

11. The method of claim 1 wherein setting an etching parameter to control the etching process occurs before etching the carbon-based layer.

12. The method of claim 1 wherein setting an etching parameter to control the etching process occurs while etching the carbon-based layer.

13. The method of claim 2 setting an etching parameter to control the etching process includes increasing and/or decreasing the flow rate of SiCl₄ with respect to the flow rates of O₂ and Cl₂ to increase and/or decrease, respectively, absolute critical dimensions of both the first portions and the second portions of the workpiece while holding the ratio of the critical dimensions in the first portion to the second portion generally constant.

14. The method of claim 1 wherein etching the carbon-based layer includes anisotropically etching the carbon-based layer to form one or more substantially vertical sidewalls in the carbon-based layer.

15. The method of claim 1, further comprising:
forming a stack of layers on the workpiece, the stack of layers including:
a polysilicon layer adjacent to the workpiece;
a conductive layer over at least a portion of the polysilicon layer;
a dielectric layer over at least a portion of the conductive layer;
the carbon-based layer over at least a portion of the dielectric layer;
an anti-reflective layer over at least a portion of the carbon-based layer; and
a patterned layer of resist over at least a portion of the DARC layer; and
etching the carbon-based layer comprises etching the carbon-based layer with an etchant comprising O₂/Cl₂/SiCl₄, and wherein the layer of resist is removed from the workpiece while etching the carbon-based layer.

16. The method of claim 15, further comprising:
etching the dielectric layer, wherein the anti-reflective layer is removed from the workpiece while etching the dielectric layer; and
removing the carbon-based layer from the workpiece.

17. A method for etching material during the fabrication of a microfeature device, the method comprising:
providing a microfeature workpiece having an array portion with features having first critical dimensions, a periphery portion with features having second critical dimensions different than the first critical dimensions, and a carbon-based layer over at least a portion of the array portion and the periphery portion;
etching the carbon-based layer using an etchant including O₂/Cl₂/SiCl₄; and
setting an etching parameter to control the etching process in the array portion relative to and independently of the etching process in the periphery portion.

18. The method of claim 17 wherein etching the carbon-based layer using an etchant including O₂/Cl₂/SiCl₄ includes etching the carbon-based layer with an etchant having a ratio of O₂ to Cl₂ to SiCl₄ of approximately 1/2/0.03.

19. The method of claim 17 wherein etching the carbon-based layer includes etching the carbon-based layer using O₂ having a flow rate of approximately 40-200 sccm, Cl₂ having a flow rate of approximately 10-100 sccm, and SiCl₄ having a flow rate of approximately 0.5-5 sccm.

20. The method of claim 17 wherein setting an etching parameter includes setting a flow rate of Cl₂.

21. The method of claim 20 wherein setting a flow rate of Cl₂ includes setting a higher flow rate of Cl₂ relative to a previous flow rate of Cl₂ to change the second critical dimensions to third critical dimensions greater than the second critical dimensions while holding the first critical dimensions generally constant.

22. The method of claim 20 wherein setting a flow rate of Cl₂ includes setting a lower flow rate of Cl₂ relative to a previous flow rate of Cl₂ to change the second critical dimensions to fourth critical dimensions less than the second critical dimensions while holding the first critical dimensions generally constant.

23. The method of claim 17 wherein setting an etching parameter to control the etching process includes setting a bias power applied to the workpiece during etching.

24. The method of claim 23 wherein setting a bias power applied to the workpiece includes setting a higher bias power relative to a previous bias power to change the first critical dimensions to third critical dimensions less than the first critical dimensions while holding the second critical dimensions generally constant.

25. The method of claim 23 wherein setting a bias power applied to the workpiece includes setting a lower bias power relative to a previous bias power to change the first critical dimensions to third critical dimensions greater than the first critical dimensions while holding the second critical dimensions generally constant.

26. The method of claim 17 wherein setting an etching parameter to control the etching process occurs before etching the carbon-based layer.

27. The method of claim 17 wherein setting an etching parameter to control the etching process occurs while etching the carbon-based layer.

28. The method of claim 17 wherein selectively varying one or more etching parameters includes increasing and/or decreasing the flow rate of SiCl₄ with respect to the flow rates of O₂ and Cl₂ to increase and/or decrease, respectively, absolute critical dimensions of both the array portion and the periphery portion of the workpiece while holding the ratio of the critical dimensions in the array portion to the periphery portion generally constant.

29. The method of claim 17 wherein etching the carbon-based layer includes anisotropically etching the carbon-based layer to form one or more substantially vertical sidewalls in the carbon-based layer.

30. A method for etching material on a workpiece during the formation of a gate structure, the workpiece including an array portion with features having first critical dimensions, a periphery portion with features having second critical dimensions different than the first critical dimensions, and a carbon-based layer over at least part of the array portion and the periphery portion, the method comprising:
etching the carbon-based layer using an etchant including O₂/Cl₂/SiCl₄; and
tuning the etching process in the array portion relative to and independently of the etching process in the periphery portion by selectively setting and/or varying an etching parameter.

31. The method of claim 30 wherein etching the carbon-based layer using an etchant including O₂/Cl₂/SiCl₄ includes etching the carbon-based layer with an etchant having a ratio of O₂ to Cl₂ to SiCl₄ of approximately 1/2/0.03.

32. The method of claim 30 wherein etching the carbon-based layer includes etching the carbon-based layer using O₂ having a flow rate of approximately 40-200 sccm, Cl₂ having a flow rate of approximately 10-100 sccm, and SiCl₄ having a flow rate of approximately 0.5-5 sccm.

33. The method of claim 30 wherein selectively setting and/or varying an etching parameter includes setting a flow rate of Cl₂.

34. The method of claim 33 wherein setting a flow rate of Cl₂ includes setting a higher flow rate of Cl₂ relative to a previous flow rate of Cl₂ to change the second critical dimensions to third critical dimensions greater than the second critical dimensions while holding the first critical dimensions generally constant.

35. The method of claim 33 wherein setting a flow rate of Cl₂ includes setting a lower flow rate of Cl₂ relative to a previous flow rate of Cl₂ to change the second critical dimensions to fourth critical dimensions less than the second critical dimensions while holding the first critical dimensions generally constant.

36. The method of claim 30 wherein selectively setting and/or varying an etching parameter includes setting a bias power applied to the workpiece during etching.

37. The method of claim 36 wherein setting a bias power applied to the workpiece includes setting a higher bias power relative to a previous bias power to change the first critical dimensions to third critical dimensions less than the first critical dimensions while holding the second critical dimensions generally constant.

38. The method of claim 36 wherein setting a bias power applied to the workpiece includes setting a lower bias power relative to a previous bias power to change the first critical dimensions to third critical dimensions greater than the first critical dimensions while holding the second critical dimensions generally constant.

39. The method of claim 30 wherein selectively setting and/or varying an etching parameter occurs before etching the carbon-based layer.

40. The method of claim 30 wherein selectively setting and/or varying an etching parameter occurs while etching the carbon-based layer.

41. The method of claim 30 wherein selectively setting and/or varying an etching parameter includes increasing and/or decreasing the flow rate of SiCl₄ with respect to the flow rates of O₂ and Cl₂ to increase and/or decrease, respectively, absolute critical dimensions of both the array portion and the periphery portion of the workpiece while holding the ratio of the critical dimensions in the array portion to the periphery portion generally constant.

42. A method for removing material from a microfeature workpiece having dies including a first portion with features having first critical dimensions, a second portion with features having second critical dimensions different than the first critical dimensions, and a carbon-based layer over at least part of the first portions and second portions, the method comprising:
selecting a value of a process parameter to provide a desired removal rate of material from the first and second portions, wherein different values of the process parameter cause the first critical dimensions to change to a different extent than the second critical dimensions; and
removing material from the workpiece with the process parameter at the selected value.

43. A method for forming a gate structure, the method comprising:
depositing a plurality of layers onto a workpiece, the plurality of layers including a polysilicon layer, a conductive layer, a dielectric layer, a carbon-based layer, an anti-reflective layer, and a layer of resist, the workpiece including an array portion and a periphery portion surrounding at least a portion of the array portion, wherein the plurality of layers are over at least a portion of the array portion and the periphery portion;
patterning the layer of resist;
etching the anti-reflective layer to form a mask of the anti-reflective layer over the carbon-based layer;
etching the carbon-based layer using an etchant including O₂/Cl₂/SiCl₄; and
selectively setting the flow of Cl₂ and/or a bias power applied to the workpiece to control the etching process in the periphery portion relative to and independently of the etching process in the array portion.

44. The method of claim 43 wherein etching the carbon-based layer using an etchant including O₂/Cl₂/SiCl₄ includes etching the carbon-based layer with an etchant having a ratio of O₂ to Cl₂ to SiCl₄ of approximately 1/2/0.03.

45. The method of claim 43 wherein etching the carbon-based layer includes etching the carbon-based layer using O₂ having a flow rate of approximately 40-200 sccm, Cl₂ having a flow rate of approximately 10-100 sccm, and SiCl₄ having a flow rate of approximately 0.5-5 sccm.

46. The method of claim 43 wherein selectively setting the flow of Cl₂ includes setting a higher flow rate of Cl₂ relative to a previous flow rate of Cl₂ to change the second critical dimensions to third critical dimensions greater than the second critical dimensions while holding the first critical dimensions generally constant.

47. The method of claim 43 wherein selectively setting the flow of Cl₂ includes setting a lower flow rate of Cl₂ relative to a previous flow rate of Cl₂ to change the second critical dimensions to fourth critical dimensions less than the second critical dimensions while holding the first critical dimensions generally constant.

48. The method of claim 43 wherein selectively setting a bias power applied to the workpiece includes setting a higher bias power relative to a previous bias power to change the first critical dimensions to third critical dimensions less than the first critical dimensions while holding the second critical dimensions generally constant.

49. The method of claim 43 wherein selectively setting a bias power applied to the workpiece includes setting a lower bias power relative to a previous bias power to change the first critical dimensions to third critical dimensions greater than the first critical dimensions while holding the second critical dimensions generally constant.

50-56. (canceled)
